(19) United States
(12) Patent Application Publication
(10) Pub. No.: US 2014/0070680 A1
(43) Pub. Date: Mar. 13, 2014

(54) PLATE-SHAPED CASING MEMBER AND INJECTION MOLDING METHOD FOR THE SAME

(71) Applicant: PANASONIC CORPORATION, Osaka (JP)

(72) Inventors: Yoshihiro KAWADA, Osaka (JP); Kenichi SHINDO, Osaka (JP); Ryo YONEZAWA, Kyoto (JP); Yoshinari MATSUYAMA, Osaka (JP); Hirofumi SASAKI, Hyogo (JP); Yoshiaki NAGAMURA, Osaka (JP)

(73) Assignee: PANASONIC CORPORATION, Osaka (JP)

(21) Appl. No.: 13/771,420

(22) Filed: Feb. 20, 2013

(30) Foreign Application Priority Data
Sep. 7, 2012 (JP) 2012-197455

(51) Int. Cl. H05K 5/04; B22D 17/00

(52) U.S. Cl. CPC H05K 5/04; B22D 17/00
USPC 312/223.1; 164/113

(57) ABSTRACT

A plate-shaped casing member is a plate-shaped casing having a front surface and a rear surface, wherein the rear surface includes a first surface, and a second surface having a height different from a height of the first surface and having a meandering contour line, and the plate-shaped casing member has a thickness from the meandering contour line in the second surface to the front surface which is different from a thickness from the first surface to the front surface.

### BACKGROUND

1. Technical Field

The present disclosure relates to plate-shaped casing members and injection molding methods for the same.

2. Background Art

In some cases, casing members for laptop personal computers are made of magnesium alloys, for realizing thickness reduction and weight reduction thereof. Since such magnesium alloys have relatively lower melting points and, therefore, such casing members have been formed through injection molding. There have been known methods adapted to provide convex formation portions in a die surface and, further, to form concave formation portions in a casing surface through injection molding such that the concave formation portions play a role as ribs for providing a preferable strength (refer to Japanese Patent Laid-Open Publication No. 2001-334356, for example).

In cases of performing injection molding using such a die having convex formation portions provided in its surface, there is induced a difference in flowability of a molten material between deeper portions and shallower portions in the die surface. For example, it flows faster at deeper portions while flowing slower at shallower portions, which may induce a temperature difference between the deeper portions and the shallower portions, thereby inducing a difference therebetween in time taken for solidification thereof. This has induced sink marks in some cases.

Furthermore, such casing members have been further required to have higher strengths, in addition to reduced thicknesses and reduced weights.

### SUMMARY OF THE INVENTION

According to the present disclosure, there is provided a plate-shaped casing member with a high strength, wherein during injection molding therefor, it is possible to suppress the occurrence of sink marks therein.

A plate-shaped casing member according to the present disclosure is a plate-shaped casing member having a front surface and a rear surface,

wherein the rear surface includes a first surface, and a second surface having a height different from a height of the first surface and having a meandering contour line, and

the plate-shaped casing member has a thickness from the meandering contour line in the second surface to the front surface which is different from a thickness from the first surface to the front surface.

Since the plate-shaped casing member includes the second surface having the meandering contour line, it is possible to suppress the occurrence of sink marks therein during injection molding therefor. Thus, the plate-shaped casing member can be preferably used as a plate-shaped casing member with a higher strength.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a plan view illustrating a plate-shaped casing member according to a first embodiment, at its rear surface;

FIG. 2 is a cross-sectional view illustrating the cross-sectional structure of the same, taken along the direction of A-A in FIG. 1;

FIG. 3 is a cross-sectional view illustrating the cross-sectional structure of the same, taken along the direction of B-B in FIG. 1;

FIG. 4 is an enlarged cross-sectional view of a portion “C” in FIG. 2;

FIG. 5 is a schematic view of level-difference portions in FIG. 4;

FIG. 6 is a perspective view illustrating the plate-shaped casing member in FIG. 1, at its rear surface;

FIG. 7 is a plan view illustrating the plate-shaped casing member in FIG. 1, at its front surface;

FIG. 8 is a perspective view illustrating the plate-shaped casing member in FIG. 7, at its front surface;

FIG. 9 is a view illustrating a yield-strength distribution when a load is being applied, in the vertical direction, to the center of the plate-shaped casing member in FIG. 1;

FIG. 10 is a partial cross-sectional view illustrating the cross-sectional structure of first and second dies for injection molding for the plate-shaped casing member according to the first embodiment, when they have been clamped to each other;

FIG. 11 is a schematic view illustrating a state where a molten material is being injected along the central direction of meanders of meandering level differences in first to sixth surfaces in the first die;

FIG. 12 is a perspective view illustrating an external appearance of a laptop personal computer employing the plate-shaped casing member according to the first embodiment in its display portion, in a state where the display portion is closed; and

FIG. 13 is a perspective view illustrating an external appearance of the laptop personal computer employing the plate-shaped casing member according to the first embodiment in its display portion, in a state where the display portion is opened.

### DETAILED DESCRIPTION OF EMBODIMENTS

A plate-shaped casing member in a first aspect of the present disclosure is a plate-shaped casing member having a front surface and a rear surface,

wherein the rear surface includes a first surface, and a second surface having a height different from a height of the first surface and having a meandering contour line, and

the plate-shaped casing member has a thickness from the meandering contour line in the second surface to the front surface which is different from a thickness from the first surface to the front surface.

In a second aspect, in the plate-shaped casing member in the aforementioned first aspect, the second surface may have a meandering level difference adjacent to the first surface.

In a third aspect, in the plate-shaped casing member in the aforementioned first aspect, the second surface may be constituted by a meandering inclined surface.

In a fourth aspect, in the plate-shaped casing member in the aforementioned second aspect, the rear surface may further include a third surface having a meandering level difference adjacent to the second surface, and the first surface, the second surface and the third surface may be adapted to have heights which are monotonously increased or decreased in the mentioned order, in a stepwise manner.

In a fifth aspect, in the plate-shaped casing member in the aforementioned fourth aspect, a thickness from the first surface to the front surface, a thickness from the second surface to the front surface, and a thickness from the third surface to the front surface may be adapted to be monotonously increased or decreased in a stepwise manner.

In a sixth aspect, in the plate-shaped casing member in the aforementioned fourth aspect, the front surface may be adapted such that its portion which aligns with the second surface in the rear surface is higher than at least one of its portion which aligns with the first surface in the rear surface and its position which aligns with the third surface.

In a seventh aspect, in the plate-shaped casing member in the aforementioned first aspect, the rear surface may further include a third surface having a height different from a height of the first surface and having a meandering contour line, in an opposite side from the second surface with respect to the first surface, and

the plate-shaped casing member has a thickness from the meandering contour line in the third surface to the front surface which may be different from a thickness from the first surface to the front surface.

In an eighth aspect, in the plate-shaped casing member in the aforementioned first aspect, the third surface may have a meandering level difference adjacent to the first surface.

In a ninth aspect, there is provided an injection molding method for a plate-shaped casing member, including:

preparing an injection molding die including a first die and a second die which can be coupled to and separated from the first die, the first die including a first surface and a second surface having a height different from a height of the first surface and having a meandering contour line, the second die including a front surface to be faced to both the first surface and the second surface in the first die when being clamped to the first die, and an interval between the meandering contour line in the second surface in the first die and the front surface in the second die faced thereto is different from an interval between the first surface in the first die and the front surface in the second die faced thereto;

clamping the first die and the second die to each other;

injecting a molten material into a cavity portion formed between the first die and the second die, along a central direction of a meander of the meandering contour line in the second surface in the first die, and, further, cooling and solidifying the molten material to form a molded material; and

opening the first die and the second die, and extracting a plate-shaped casing member made of the molded material resulted from the injection molding.

In a tenth aspect, in the injection molding method for the plate-shaped casing member in the aforementioned ninth aspect, the second surface may have a meandering level difference adjacent to the first surface.

In an eleventh aspect, in the injection molding method for the plate-shaped casing member in the aforementioned ninth aspect, the second surface may be constituted by a meandering inclined surface.

In a twelfth aspect, in the injection molding method for the plate-shaped casing member in the aforementioned tenth aspect, the first die may further include a third surface having a meandering level difference adjacent to the second surface, and the first surface, the second surface and the third surface may be adapted to have heights which are monotonously increased or decreased in the mentioned order, in a stepwise manner.

In a thirteenth aspect, in the injection molding method for the plate-shaped casing member in the aforementioned twelfth aspect, an interval between the first surface in the first die and the front surface in the second die faced thereto, an interval between the second surface in the first die and the front surface in the second die faced thereto, and an interval between the third surface in the first die and the front surface in the second die faced thereto may be adapted to be monotonously increased or decreased in a stepwise manner.

In a fourteenth aspect, in the injection molding method for the plate-shaped casing member in the aforementioned twelfth aspect, the front surface in the second die may be adapted such that its portion which aligns with the second surface in the first die is lower than at least one of its portion which aligns with the first surface in the rear surface and its position which aligns with the third surface.

Hereinafter, an embodiment will be described in detail, with reference to the drawings, appropriately. However, descriptions in detail more than necessary may be omitted. For example, matters which have been already well known may not be described in detail, and substantially the same structures may not be described redundantly. This is for avoiding the following descriptions from being unnecessarily redundant for allowing those skilled in the art to easily understand them.

Further, the present inventors give the accompanying drawings and the following descriptions for allowing those skilled in the art to sufficiently understand the present disclosure, and the subject defined in the claims is not intended to be restricted thereby. Further, in the drawings, like reference characters refer to substantially the same members.

### First Embodiment

### As to Plate-Shaped Casing Member:

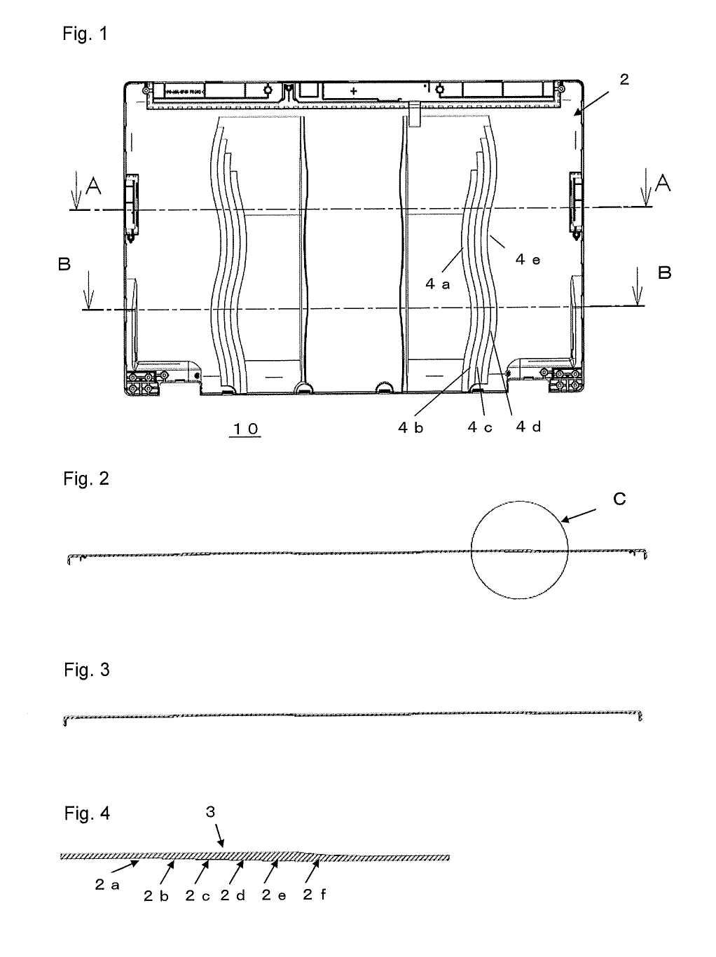

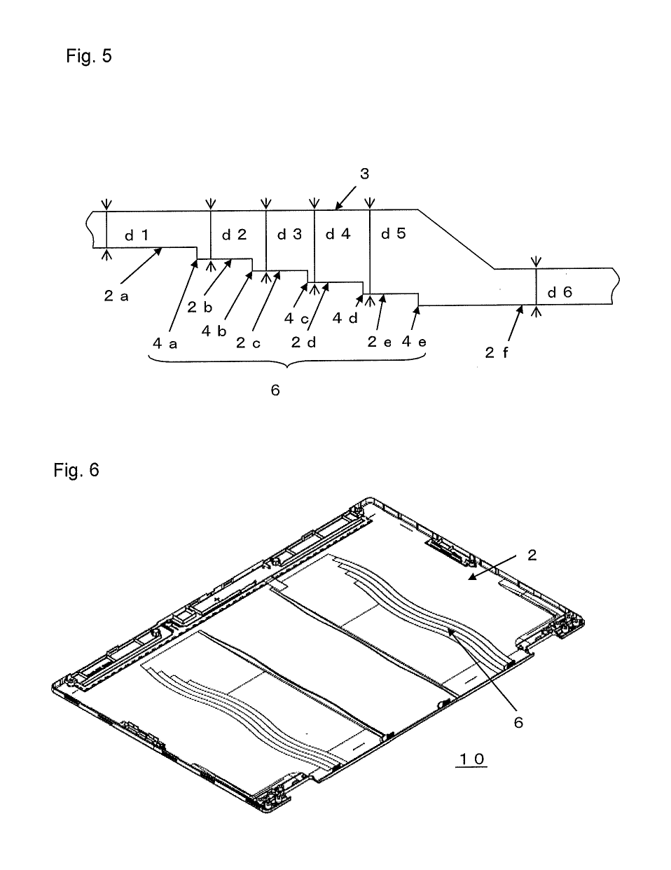

FIG. 1 is a plan view illustrating a plate-shaped casing member 10 according to a first embodiment, at its rear surface. FIG. 2 is a cross-sectional view illustrating the cross-sectional structure of the same, taken along the direction of A-A in FIG. 1. FIG. 3 is a cross-sectional view illustrating the cross-sectional structure of the same, taken along the direction of B-B in FIG. 1. FIG. 4 is an enlarged cross-sectional view of a portion C in FIG. 2. FIG. 5 is a schematic view of level-difference portions in FIG. 4. The plate-shaped casing member 10 includes a front surface 3 and a rear surface 2.

The rear surface 2 includes a first surface 2a, a second surface 2b having a meandering level difference 4a adjacent to the first surface 2a, a third surface 2c having a meandering level difference 4b adjacent to the second surface 2b, a fourth surface 2d having a meandering level difference 4c adjacent to the third surface 2c, a fifth surface 2e having a meandering level difference 4d adjacent to the fourth surface 2d, and a sixth surface 2f having a meandering level difference 4e adjacent to the fifth surface 2e. The plate-shaped casing member 10 is characterized by the meandering wave-shaped level differences 4a, 4b, 4c, 4d and 4e. The areas of these meandering level differences 4a to 4e constitute a meandering portion 6. The meandering portion 6 can suppress deformations due to stresses. More specifically, the wave-shaped meandering portion 6 can disperse, in the leftward and rightward directions, stresses applied thereto in in-plane directions (directions parallel to the surface), which can suppress deformations due to stresses in in-plane directions. Further, the meandering portion 6 can play a role as a rib, which can improve the stress resistance, thereby enabling the plate-shaped casing member 10 to have an excellent strength.

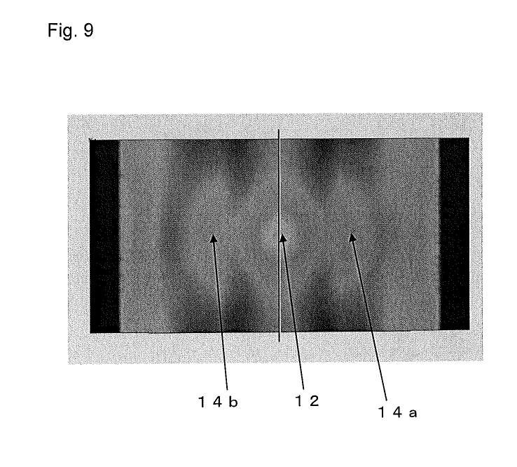

FIG. 9 is a view illustrating a yield-strength distribution when a load is being applied, in the vertical direction, to the center 12 of the plate-shaped casing member 10 in FIG. 1. As illustrated in FIG. 9, there are induced yield-strength peaks at two positions 14a and 14b where there is provided the meandering portion 6, besides the center 12 to which the load is being applied. This indicates that, even when a load is being applied to the center 12, the load is supported at the two positions 14a and 14b where there is provided the meandering portion 6, wherein the two positions 14a and 14b are deviated from the center. Namely, by providing the meandering portion 6 in the rear surface 2, it is possible to improve the stress resistance for coping with stresses applied to the surface in the vertical direction.

Hereinafter, the components constituting the plate-shaped casing member 10 will be described.

### As to the Rear Surface:

The plate-shaped casing member 10 includes the first surface 2a, the second surface 2b, the third surface 2c, the fourth surface 2d, the fifth surface 2e and the sixth surface 2f, in its rear surface, 2, as described above. The plate-shaped casing member 10 further includes the meandering wave-shaped level differences 4a, 4b, 4c, 4d and 4e, between the respective surfaces 2a, 2b, 2c, 2d, 2e and 2f. The areas of these meandering level differences 4a to 4e constitute the meandering portion 6.

Further, although, in this case, the meandering level differences 4a to 4e are provided, it is necessary to provide only at least a single meandering level difference. In cases where a plurality of level differences are provided, it is possible to further improve the strength.

Further, the thickness d1 from the first surface 2a to the front surface 3, the thickness d2 from the second surface 2b to the front surface 3, the thickness d3 from the third surface 2c to the front surface 3, the thickness d4 from the fourth surface 2d to the front surface 3 and the thickness d5 from the fifth surface 2e to the front surface 3 are set such that they are different from each other. In this case, the thicknesses d1 to d5 are made to be monotonously increased. According to the monotonously increased thickness d1 to d5, it is not necessary to provide a concave portion halfway through the continuous surfaces. The monotonously increased thickness d1 to d5 can further improve the stress resistance.

Further, although the plate-shaped casing member 10 is provided with the meandering portions 6 at two portions in the left and right sides with respect to the center, the meandering portion 6 may be provided at least at only a single position. Also, the meandering portions 6 may be provided at four positions, for example.

Further, although the plate-shaped casing member 10 is provided with the meandering level differences 4a, 4b, 4c, 4d and 4e between the respective surfaces 2a, 2b, 2c, 2d, 2e and 2f, the respective surfaces can be also adapted to have meandering contour lines, as well as meandering level differences. Also, the respective surfaces can be adapted to form meandering inclined surfaces, for example, out of surfaces having meandering contour lines.

### As to the Front Surface:

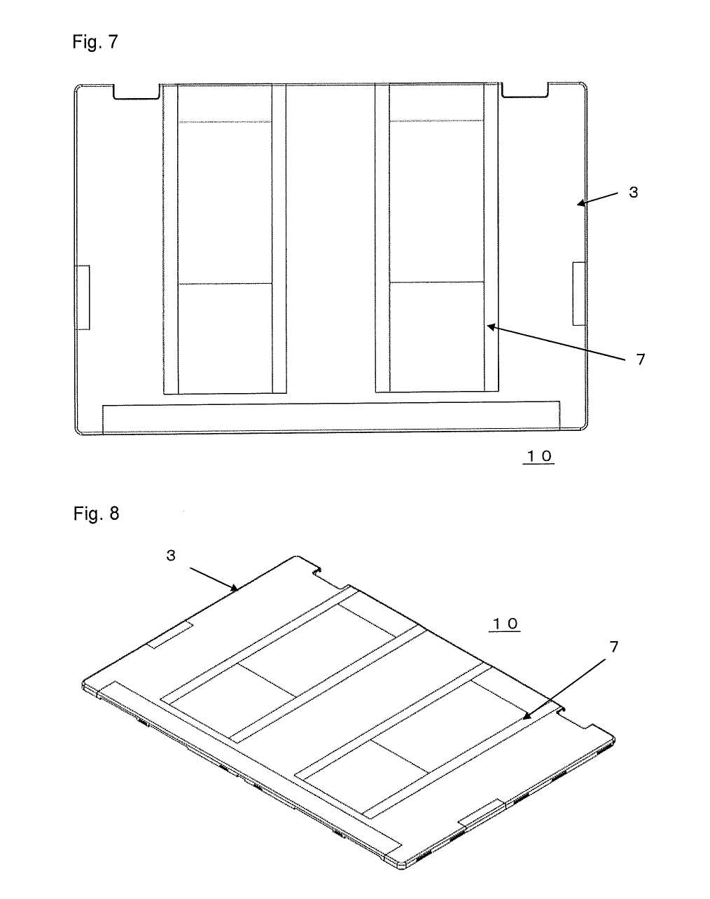

FIG. 7 is a plan view illustrating the plate-shaped casing member 10 in FIG. 1, at its front surface 3. Further, FIG. 8 is a perspective view illustrating the plate-shaped casing member 10 in FIG. 7, at its front surface 3.

Further, the plate-shaped casing member 10 can be also provided, in its front surface 3, with various structures for improving the strength, decorations for providing aesthetic appearances, and the like. For example, it is possible to provide a bonnet structure 7 having convex portions with a trapezoidal shape, in the front surface 3. Further, it is possible to provide meandering level differences 4 in the rear surface 2 at positions which align with height-difference portions of the bonnet structure 7 in the front surface 3. Namely, at positions where there are induced height differences in the front surface 3, level differences 4 can be provided for inducing height differences in the rear surface 2 similarly thereto, as illustrated in FIG. 5. In a concrete example, at first, as illustrated in FIG. 5, a level difference 4a is to exist at a highest position among the level differences 4 (4a, 4b, 4c, 4d, 4e), and the front surface 3 is formed by the bonnet structure 7, thus, the level difference 4a is formed in the rear surface, at a position aligned with a higher position in the front surface 3. Subsequently, a level difference 4e is to exist at a lowest position among the level differences 4(4a, 4b, 4c, 4d, 4e), the front surface 3 is formed by the bonnet structure 7, thus, the level difference 4e is formed at a gap between a higher position and a lower position in the front surface 3 or at the boundary therebetween. According to the bonnet structure 7 provided in the front surface 3, the plate-shaped casing member 10 is enabled to have a higher strength.

Further, the front surface 3 can be adapted such that its portion which aligns with the second surface 2b in the rear surface 2 is higher than at least one of its portion which aligns with the first surface 2a in the rear surface 2 and its position which aligns with the sixth surface 2f. For example, in the cross-sectional view in FIG. 5, the front surface 3 is adapted such that its portion which aligns with the second surface 2b in the rear surface 2 is higher than its portion which aligns with the sixth surface 2f. Also, the height differences in the front surface can be made coincident with portions of the height differences in the bonnet structure 7.

### As to Injection Molding Method for the Plate-Shaped Casing Member:

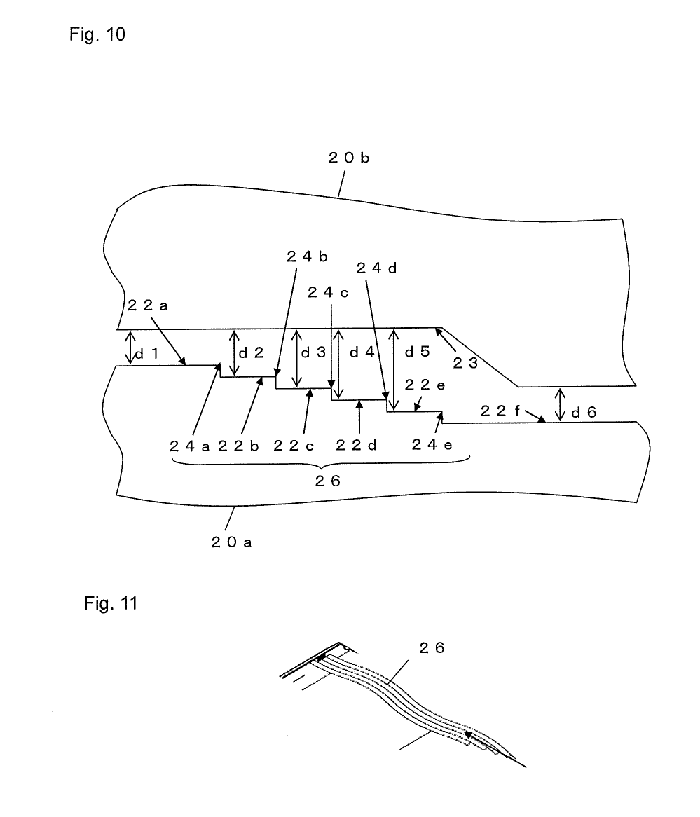

FIG. 10 is a partial cross-sectional view illustrating the cross-sectional structure of first and second dies 20a and 20b for injection molding for the plate-shaped casing member according to the first embodiment, when they have been clamped to each other. FIG. 11 is a schematic view illustrating a state where a molten material is being injected along the central direction of the meanders of meandering level differences 24a, 24b, 24c, 24d and 24e in a first surface 22a to a sixth surface 22f in the first die 20a.

(1) An injection molding die is prepared, wherein the injection molding die includes the first die 20a and the second die 20b which can be coupled to and separated from the first die 20a.

The first die 20a includes the first surface 22a, a second surface 22b, a third surface 22c, a fourth surface 22d, a fifth surface 22e, and the sixth surface 22f. The first surface 22a to the sixth surface 22f have the stepped level differences 24a, 24b, 24c, 24d and 24e. The respective level differences 24a, 24b, 24c, 24d and 24e are meandering. The areas of these meandering level differences 24a to 24e constitute a meandering portion 26.

The second die 20b includes a front surface 23 to be faced to the first surface 22a, the second surface 22b, the third surface 22c, the fourth surface 22d, the fifth surface 22e and the sixth surface 22f in the first die 20a, when it has been clamped to the first die 20a.

In this case, the interval d1 between the first surface 22a in the first die 20a and the front surface 23 in the second die 20b faced thereto, the interval d2 between the second surface 22b in the first die 20a and the front surface 23 in the second die 20b faced thereto, the interval d3 between the third surface 22c in the first die 20a and the front surface 23 in the second die 20b faced thereto, the interval d4 between the fourth surface 22d in the first die 20a and the front surface 23 in the second die 20b faced thereto, and the interval d5 between the fifth surface 22a in the first die 20a and the front surface 23 in the second die 20b faced thereto are set such that they are different from each other.

(2) The first die 20a and the second die 20b are clamped to each other.

(3) A molten material is injected into the cavity portion formed between the first die 20a and the second die 20b, along the central direction (an arrow) of the meanders of the respective meandering level differences 24a, 24b, 24c, 24d and 24e in the first die 20a (FIG. 11) and, further, the molten material is cooled and solidified to form a molded material. Since the molten material is flowed thereinto along the central direction of the meanders of the level difference 24a, as described above, the molten material is dispersed leftwardly and rightwardly through the meandering wave-shaped level differences 24a, 24b, 24c, 24d and 24e, which can uniformize the material flows. Namely, along the thicker portions, greater amounts of the molten material are flowed faster and, thus, are dispersed toward the thinner portions, which can uniformize the entire material flows. In this case, each level difference 24a, 24b, 24c, 24d, 24e has a thickness of only about several millimeters, for example. However, since they are meandering, they can serve as barrier walls for applying brakes to the material flows.

(4) The first die 20a and the second die 20b are opened, and the injection-molded article (the plate-shaped casing member 10) made of the molded material resulted from the injection molding is extracted therefrom.

Through the aforementioned manner, the plate-shaped casing member 10 can be provided.

With the injection molding method for the plate-shaped casing member 10, due to the meandering portion 26 provided in the front surface of the first die 32, it is possible to uniformize flows of the molten material, which suppresses the occurrence of temperature differences, thereby suppressing the occurrence of sink marks.

Hereinafter, there will be described the respective components for use in the injection molding method for the plate-shaped casing member.

### As to the First Die:

The first die 20a includes the first surface 22a, the second surface 22b, the third surface 22c, the fourth surface 22d, the fifth surface 22e and the sixth surface 22f. The first surface 22a to the sixth surface 22f have the stepped level differences 24a, 24b, 24c, 24d and 24e. The respective level differences 24a, 24b, 24c, 24d and 24e are meandering. The level differences 24a, 24b, 24c, 24d and 24e can be adapted to have thicknesses of several millimeters, for example. The areas of these meandering level differences 24a to 24e constitute the meandering portion 26.

### As to the Second Die:

The second die 20b includes the front surface 23 to be faced to the first surface 22a, the second surface 22b, the third surface 22c, the fourth surface 22d, the fifth surface 22e and the sixth surface 22f in the first die 20a, when it has been clamped to the first die 20a. The interval d1 between the first surface 22a in the first die 20a and the front surface 23 in the second die 20b faced thereto, the interval d2 between the second surface 22b in the first die 20a and the front surface 23 in the second die 20b faced thereto, the interval d3 between the third surface 22c in the first die 20a and the front surface 23 in the second die 20b faced thereto, the interval d4 between the fourth surface 22d in the first die 20a and the front surface 23 in the second die 20b faced thereto, and the interval d5 between the fifth surface 22a in the first die 20a and the front surface 23 in the second die 20b faced thereto are made to be monotonously increased.

### As to the Molten Material:

As the molten material, it is possible to employ a molten material made of a metal alloy having a lower melting point, such as a magnesium alloy, for example. However, the molten material is not limited to a magnesium alloy.

### As to Laptop Personal Computer:

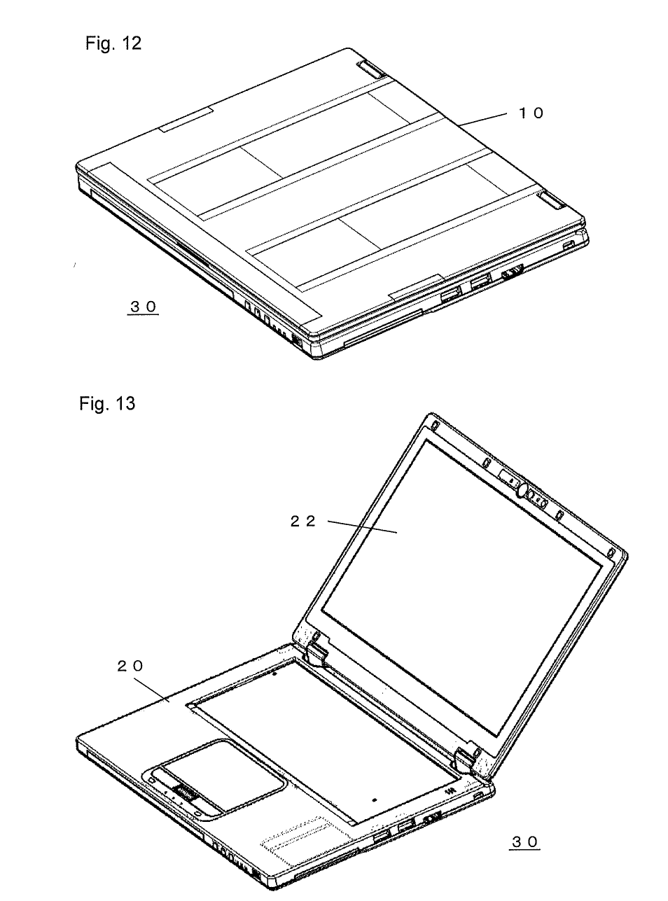

FIG. 12 is a perspective view illustrating an external appearance of a laptop personal computer 30 employing the plate-shaped casing member 10 according to the first embodiment in its display portion, in a state where the display portion is closed. FIG. 13 is a perspective view illustrating an external appearance of the laptop personal computer 30 employing the plate-shaped casing member 10 according to the first embodiment in its display portion, in a state where the display portion is opened.

The laptop personal computer 30 includes the plate-shaped casing member (an upper casing) 10 employed in the display portion for holding a display 22 and, further, includes a lower casing 20. Since the plate-shaped casing member 10 as the upper casing includes the meandering portion 6 and, therefore, has an excellent strength, the laptop personal computer 30 can have an excellent strength.

As described above, an embodiment has been described as an example of the techniques according to the present disclosure. For convenience, the accompanying drawings and the detailed description have been given.

Accordingly, the constituents described in the accompanying drawings and the detailed description may also include constituents which are unnecessary for overcoming the problems, in order to exemplify the aforementioned techniques, as well as constituents necessary for overcoming the problems. Therefore, such unnecessary constituents should not be immediately determined to be necessary, for the reason that these unnecessary constituents are described in the accompanying drawings and the detailed description.

Further, the aforementioned embodiment is merely for exemplifying the techniques according to the present disclosure and, therefore, various changes, replacements, additions, omissions and the like can be made thereto within the scope of the claims and scopes equivalent thereto.

The present disclosure can suppress the occurrence of sink marks during injection molding and can be applied to plate-shaped casing members with higher strengths. More specifically, the present disclosure can be applied to plate-shaped casing members for electronic apparatuses such as laptop personal computers.

What is claimed is:

1. A plate-shaped casing member having a front surface and a rear surface,
wherein the rear surface includes a first surface, and a second surface having a height different from a height of the first surface and having a meandering contour line, and
the plate-shaped casing member has a thickness from the meandering contour line in the second surface to the front surface which is different from a thickness from the first surface to the front surface.

2. The plate-shaped casing member according to claim 1, wherein the second surface has a meandering level difference adjacent to the first surface.

3. The plate-shaped casing member according to claim 1, wherein the second surface comprises a meandering inclined surface.

4. The plate-shaped casing member according to claim 2, wherein the rear surface further includes a third surface having a meandering level difference adjacent to the second surface, and
the first surface, the second surface and the third surface are adapted to have heights which are monotonously increased or decreased in the mentioned order, in a stepwise manner.

5. The plate-shaped casing member according to claim 4, wherein a thickness from the first surface to the front surface, a thickness from the second surface to the front surface, and a thickness from the third surface to the front surface are adapted to be monotonously increased or decreased in a stepwise manner.

6. The plate-shaped casing member according to claim 4, wherein the front surface is adapted such that its portion which aligns with the second surface in the rear surface is higher than at least one of its portion which aligns with the first surface in the rear surface and its position which aligns with the third surface.

7. The plate-shaped casing member according to claim 1, wherein
the rear surface further includes a third surface having a height different from a height of the first surface and having a meandering contour line, in an opposite side from the second surface with respect to the first surface, and
the plate-shaped casing member has a thickness from the meandering contour line in the third surface to the front surface which is different from a thickness from the first surface to the front surface.

8. The plate-shaped casing member according to claim 7, wherein the third surface has a meandering level difference adjacent to the first surface.

9. An injection molding method for a plate-shaped casing member, comprising:
preparing an injection molding die including a first die and a second die which can be coupled to and separated from the first die, the first die including a first surface and a second surface having a height different from a height of the first surface and having a meandering contour line, the second die including a front surface to be faced to both the first surface and the second surface in the first die when being clamped to the first die, and an interval between the meandering contour line in the second surface in the first die and the front surface in the second die faced thereto is different from an interval between the first surface in the first die and the front surface in the second die faced thereto;
clamping the first die and the second die to each other;
injecting a molten material into a cavity portion formed between the first die and the second die, along a central direction of a meander of the meandering contour line in the second surface in the first die, and, further, cooling and solidifying the molten material to form a molded material; and
opening the first die and the second die, and extracting a plate-shaped casing member made of the molded material resulted from the injection molding.

10. The injection molding method for the plate-shaped casing member according to claim 9, wherein the second surface has a meandering level difference adjacent to the first surface.

11. The injection molding method for the plate-shaped casing member according to claim 9, wherein the second surface comprises a meandering inclined surface.

12. The injection molding method for the plate-shaped casing member according to claim 10,
wherein the first die further includes a third surface having a meandering level difference adjacent to the second surface, and
the first surface, the second surface and the third surface are adapted to have heights which are monotonously increased or decreased in the mentioned order, in a stepwise manner.

13. The injection molding method for the plate-shaped casing member according to claim 12,
wherein an interval between the first surface in the first die and the front surface in the second die faced thereto, an interval between the second surface in the first die and the front surface in the second die faced thereto, and an interval between the third surface in the first die and the front surface in the second die faced thereto are adapted to be monotonously increased or decreased in a stepwise manner.

14. The injection molding method for the plate-shaped casing member according to claim 12,
wherein the front surface in the second die is adapted such that its portion which aligns with the second surface in the first die is lower than at least one of its portion which aligns with the first surface in the rear surface and its position which aligns with the third surface.
